(19) United States
(12) Patent Application Publication
(10) Pub. No.: US 2012/0264300 A1
(43) Pub. Date: Oct. 18, 2012

(54) METHOD OF FABRICATING SEMICONDUCTOR COMPONENT

(75) Inventors: Chien-Mao Liao, Taipei County (TW); Yi-Nan Chen, Taipei City (TW); Hsien-Wen Liu, Taoyuan County (TW)

(73) Assignee: NANYA TECHNOLOGY CORPORATION, Taoyuan (TW)

(21) Appl. No.: 13/086,366

(22) Filed: Apr. 13, 2011

(51) Int. Cl. H01L 21/306

(52) U.S. Cl. 438/692; 257/E21.23

(57) ABSTRACT

A method of fabricating the semiconductor component including following steps is provided. A substrate is provided, wherein an opening is already formed in the substrate. A material layer is formed on the substrate, wherein the material layer fills up the opening, and the material layer outside and above the opening has a recess therein. A sacrifice layer is formed on a surface of the recess. A chemical mechanical polishing (CMP) process is performed to remove the sacrifice layer and the material layer outside the opening, wherein a polishing rate of the CMP process on the material layer is greater than that of the CMP process on the sacrifice layer.

### BACKGROUND OF THE INVENTION

1. Field of the Invention

The invention generally relates to a method of fabricating a semiconductor component, and more particularly, to a method of fabricating a semiconductor component that can lower a step height.

2. Description of Related Art

Because the resolution of photolithography exposure increases along with the decrease in device size and the depth of field at exposure is reduced, the requirement to flatness of chip surface increases drastically. Thus, when performing the deep sub-micron process, the planarization of the chip then depends on the chemical mechanical polishing (CMP) process. The unique anisotropic polishing property of the CMP process is not only used for the planarization of the surface contour of the chip, but can also be applied in the fabrication of damascene structures of perpendicular and horizontal metal interconnections, the fabrication of shallow trench isolations in devices and the fabrication of advanced devices in the previous stage, and the fabrication of micro-electromechanical system planarization and the fabrication of flat displays, etc.

The CMP process mainly utilizes a reagent in the polishing slurry for generating a chemical reaction on the front side of the wafer to form a polishable layer. Further, with the wafer on the polishing pad, the protruding portions of the polishable layer are polished off by the mechanical polishing with the facilitation of abrasive particles in the polishing slurry. The chemical reactions and the mechanical polishing are then repeated to form a planar surface.

In a gap-filling process, any extra material layer outside an opening is usually removed through CMP. However, when the aspect ratio of the opening is too large, a recess will be formed in the material layer above the opening. If the step height of the recess is too large (for example, at the μm level), the recess cannot be planarized by performing the CMP process. Thus, a dishing effect is generated in the material layer filling inside the opening. As a result, the flatness of the material layer is bad and the reliability of the semiconductor component is reduced.

### SUMMARY OF THE INVENTION

Accordingly, the invention is directed to a method of fabricating a semiconductor component that can lower a step height and prohibit the generation of dishing effect.

The invention provides a method of fabricating a semiconductor component including following steps. A substrate is provided, wherein an opening is already formed in the substrate. A material layer is formed on the substrate, wherein the material layer fills up the opening, and the material layer outside and above the opening has a recess therein. A sacrifice layer is formed on a surface of the recess. A chemical mechanical polishing (CMP) process is performed to remove the sacrifice layer and the material layer outside the opening, wherein a polishing rate of the CMP process on the material layer is greater than that of the CMP process on the sacrifice layer.

According to an embodiment of the invention, in the method of fabricating the semiconductor component, the depth of the opening may be between 70 μm and 150 μm.

According to an embodiment of the invention, in the method of fabricating the semiconductor component, the width of the opening may be between 10 μm and 40 μm.

According to an embodiment of the invention, in the method of fabricating the semiconductor component, the aspect ratio of the opening may be between 1.8 and 15.

According to an embodiment of the invention, in the method of fabricating the semiconductor component, the step height of the recess may be between 2 μm and 4 μm.

According to an embodiment of the invention, in the method of fabricating the semiconductor component, the material of the material layer may be a metal material.

According to an embodiment of the invention, in the method of fabricating the semiconductor component, the method of forming the sacrifice layer includes following steps. A sacrifice material layer is formed on the material layer. The sacrifice material layer outside the recess is removed.

According to an embodiment of the invention, in the method of fabricating the semiconductor component, the method of removing the sacrifice material layer outside the recess may be a CMP method.

According to an embodiment of the invention, in the method of fabricating the semiconductor component, the material of the sacrifice layer may be a dielectric material.

According to an embodiment of the invention, in the method of fabricating the semiconductor component, the semiconductor component may be a through-silicon via (TSV) structure.

As described above, in the method of fabricating the semiconductor component provided by the invention, the sacrifice layer is formed on the surface of the recess in the material layer, and the polishing rate of the CMP process on the material layer is greater than that of the CMP process on the sacrifice layer. Thus, the step height of the recess in the material layer can be effectively lowered. Thereby, the method of fabricating the semiconductor component provided by the invention can improve the surface flatness of the polished material layer and prohibit the generation of dishing effect, so that the reliability of the semiconductor component fabricated through the method can be improved.

These and other exemplary embodiments, features, aspects, and advantages of the invention will be described and become more apparent from the detailed description of exemplary embodiments when read in conjunction with accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1D are cross-sectional views illustrating the fabricating process of a semiconductor component according to an embodiment of the invention.

### DESCRIPTION OF THE EMBODIMENTS

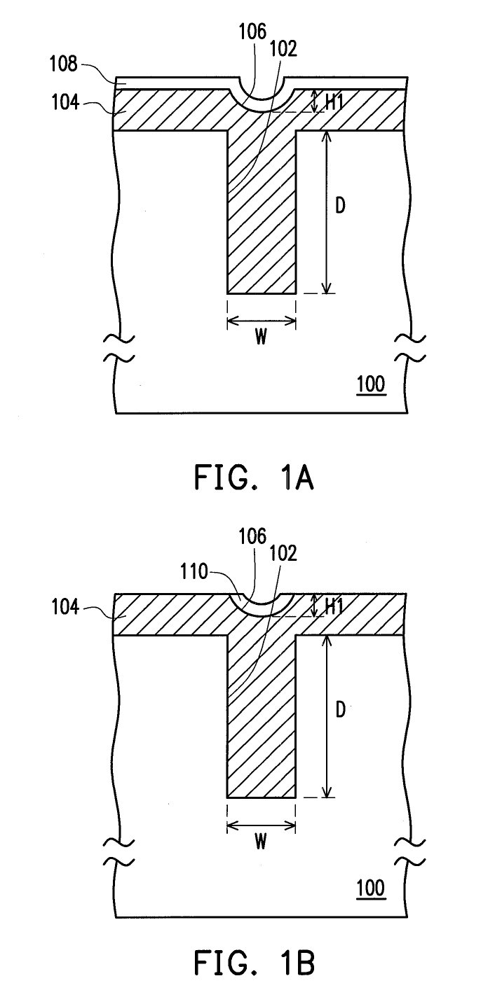

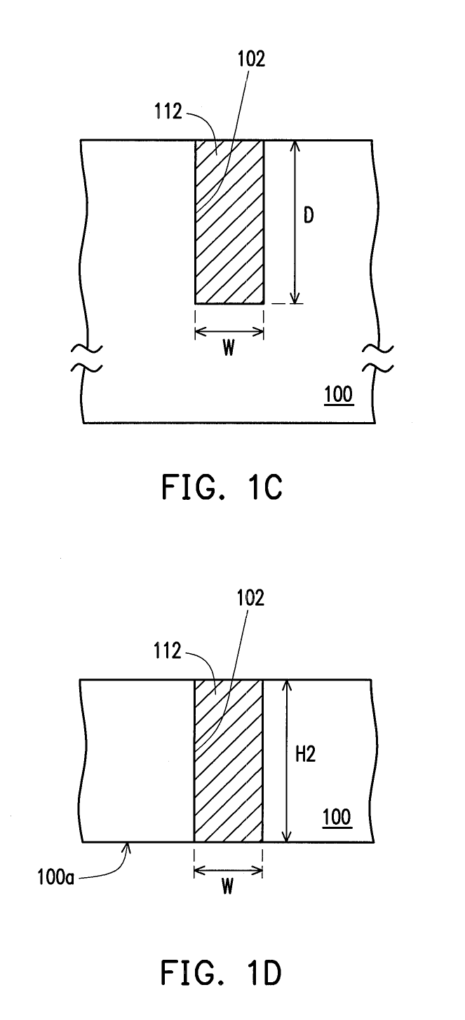

FIGS. 1A-1D are cross-sectional views illustrating the fabricating process of a semiconductor component according to an embodiment of the invention. In the present embodiment, the semiconductor component may be a component for forming a semiconductor device, such as an electrode, a conductive line, a contact plug, a via plug, or a through-silicon via (TSV) structure.

Referring to FIG. 1A, a substrate 100 is provided, wherein an opening 102 is already formed in the substrate 100. The substrate 100 may be a silicon substrate. The opening 102 may be formed by performing a photolithography process and an etching process on the substrate 100.

A material layer 104 is formed on the substrate 100, wherein the material layer 104 fills up the opening 102, and the material layer 104 outside and above the opening 102 has a recess 106 therein. The material of the material layer 104 may be a metal material, such as copper. The material layer 104 may be formed through physical vapour deposition (PVD). The depth D of the opening 102 may be between 70 μm and 150 μm. The width W of the opening 102 may be between 10 μm and 40 μm. The aspect ratio of the opening 102 may be between 1.8 and 15. The step height H1 of the recess 106 may be between 2 μm and 4 μm.

A sacrifice material layer 108 is formed on the material layer 104. The material of the sacrifice material layer 108 may be a dielectric material, photoresist or poly silicon, and it is different from the material of the material layer 104. The dielectric material may be nitride or oxide.

Referring to FIG. 1B, the sacrifice material layer 108 outside the recess 106 is removed to form a sacrifice layer 110 on the surface of the recess 106. The sacrifice material layer 108 outside the recess 106 may be removed through chemical mechanical polishing (CMP). Even though the sacrifice layer 110 may be formed through aforementioned method, the formation method of the sacrifice layer 110 is not limited thereto.

Referring to FIG. 1C, a CMP process is performed to remove the sacrifice layer 110 and the material layer 104 outside the opening 102, so that the material layer 104 inside the opening 102 forms a semiconductor component 112. Herein, the polishing rate of the CMP process on the material layer 104 is greater than that of the CMP process on the sacrifice layer 110. Accordingly, the step height H1 of the recess 106 can be effectively lowered and the semiconductor component 112 is allowed to have a planar surface. In the present embodiment, the semiconductor component 112 may be a component for forming a semiconductor device, such as an electrode, a conductive line, a contact plug, a via plug, or a TSV structure.

When the semiconductor component 112 is a TSV structure, referring to FIG. 1D, part of the substrate 100 is further removed from the back surface 100a of the substrate 100 until the semiconductor component 112 is exposed. Herein, the height H2 of the semiconductor component 112 is determined by the extent of the part of the substrate 100 that is removed, and the height H2 may be between 30 μm and 60 μm. The part of the substrate 100 may be removed through CMP.

It should be noted that even though in the present embodiment, the material of the material layer 104 is assumed to be a metal material and the material of the sacrifice layer 110 is assumed to be a dielectric material, the invention is not limited thereto. The material of the material layer 104 can be determined by those having ordinary knowledge in the art according to the semiconductor component 112 to be fabricated, and it is within the scope of the invention as long as the materials of the material layer 104 and the sacrifice layer 110 have different polishing rates.

Additionally, another layer (for example, a dielectric layer (not shown) or a barrier layer (not shown)) may be selectively formed between the material layer 104 and the substrate 100, which can be designed by those having ordinary knowledge in the art according to the semiconductor component 112 to be fabricated.

Based on the embodiment described above, because the sacrifice layer 110 is formed on the surface of the recess 106 in the material layer 104 and the polishing rate of the CMP process on the material layer 104 is greater than that of the CMP process on the sacrifice layer 110, the step height H1 of the recess 106 in the material layer 104 can be effectively lowered. Thereby, the surface flatness of the polished material layer 104 can be improved and the generation of dishing effect can be prohibited, so that a highly reliable semiconductor component 112 can be fabricated.

In summary, the method of fabricating the semiconductor component in an embodiment of the invention has at least following features:

1. the method of fabricating the semiconductor component can effectively lower the step height at the recess in the material layer;

2. the method of fabricating the semiconductor component can improve the reliability of a semiconductor component.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A method of fabricating a semiconductor component, comprising:
providing a substrate, wherein an opening is already formed in the substrate;
forming a material layer on the substrate, wherein the material layer fills up the opening, and the material layer outside and above the opening has a recess therein;
forming a sacrifice layer on a surface of the recess; and
performing a chemical mechanical polishing (CMP) process to remove the sacrifice layer and the material layer outside the opening, wherein a polishing rate of the CMP process on the material layer is greater than a polishing rate of the CMP process on the sacrifice layer.

2. The method of fabricating the semiconductor component according to claim 1, wherein a depth of the opening is between 70 μm and 150 μm.

3. The method of fabricating the semiconductor component according to claim 1, wherein a width of the opening is between 10 μm and 40 μm.

4. The method of fabricating the semiconductor component according to claim 1, wherein an aspect ratio of the opening is between 1.8 and 15.

5. The method of fabricating the semiconductor component according to claim 1, wherein a step height of the recess is between 2 μm and 4 μm.

6. The method of fabricating the semiconductor component according to claim 1, wherein a material of the material layer comprises a metal material.

7. The method of fabricating the semiconductor component according to claim 1, wherein a method of forming the sacrifice layer comprises:
forming a sacrifice material layer on the material layer; and
removing the sacrifice material layer outside the recess.

8. The method of fabricating the semiconductor component according to claim 7, wherein a method of removing the sacrifice material layer outside the recess comprises a CMP method.

9. The method of fabricating the semiconductor component according to claim 1, wherein a material of the sacrifice layer comprises a dielectric material.

10. The method of fabricating the semiconductor component according to claim 1, wherein the semiconductor component comprises a through-silicon via (TSV) structure.
